(19) United States
(12) Patent Application Publication
(10) Pub. No.: US 2015/0014762 A1
(43) Pub. Date: Jan. 15, 2015

(54) NONVOLATILE SEMICONDUCTOR STORAGE DEVICE AND METHOD OF MANUFACTURING THE SAME

(71) Applicant: KABUSHIKI KAISHA TOSHIBA, Minato-ku (JP)

(72) Inventor: Ryota OHNUKI, Yokkaichi (JP)

(73) Assignee: KABUSHIKI KAISHA TOSHIBA, Minato-ku (JP)

(21) Appl. No.: 14/177,622

(22) Filed: Feb. 11, 2014

(30) Foreign Application Priority Data
Jul. 10, 2013 (JP) 2013-144569

(51) Int. Cl. H01L 29/423; H01L 21/28; H01L 29/788

(52) U.S. Cl. CPC H01L 29/42324; H01L 29/788; H01L 21/28273
USPC 257/316; 438/593

(57) ABSTRACT

A semiconductor storage device is disclosed. The semiconductor device includes a semiconductor substrate; and a gate electrode disposed above the semiconductor substrate. The gate electrode includes a conductive film, a metal film, and a first insulating film. In a cross sectional view of the gate electrode, at least the metal film includes a receding portion receding in a lateral direction as compared to the first insulating film, and wherein a second insulating film is disposed in the receding portion and contacts sidewalls of the metal film.

### CROSS-REFERENCE TO RELATED APPLICATION(S)

This application is based upon and claims the benefit of priority from Japanese Patent Application No. 2013-144569, filed on, Jul. 10, 2013 the entire contents of which are incorporated herein by reference.

### FIELD

Embodiments disclosed herein generally relate to a nonvolatile semiconductor storage device and a method of manufacturing the same.

### BACKGROUND

Transistors implemented in a semiconductor device may adopt a gate electrode including a metal film. During the formation of the gate electrode, the metal film may scatter or dissolve into chemical liquids used in the manufacturing process flow.

### BRIEF DESCRIPTION OF THE DRAWINGS

FIG. 1 is one example of a block diagram schematically illustrating an electrical configuration of a NAND Flash memory device of one embodiment.

FIG. 2 is one schematic example of a planar layout of memory cell region M in part.

FIG. 3 illustrates one example of a vertical cross sectional view illustrating the structure and one phase of the manufacturing process flow of a NAND flash memory device of a first embodiment and is one schematic example of a cross-sectional view taken along line 3-3 of FIG. 2.

FIG. 4 is one example of a vertical cross sectional view for explaining one phase of the manufacturing process flow of the NAND flash memory device of the first embodiment.

FIG. 5 is one example of a vertical cross sectional view for explaining one phase of the manufacturing process flow of the NAND flash memory device of the first embodiment.

FIG. 6 is one example of a vertical cross sectional view for explaining one phase of the manufacturing process flow of the NAND flash memory device of the first embodiment.

FIG. 7 is one example of a vertical cross sectional view for explaining one phase of the manufacturing process flow of the NAND flash memory device of the first embodiment.

FIG. 8 is one example of a vertical cross sectional view for explaining one phase of the manufacturing process flow of the NAND flash memory device of the first embodiment.

FIG. 9 is one example of a vertical cross sectional view schematically illustrating the structure and the manufacturing process flow of the NAND flash memory device of the first embodiment.

FIG. 10 is one example of a vertical cross sectional view schematically illustrating the structure and the manufacturing process flow of a NAND flash memory device of a second embodiment.

FIG. 11 is one example of a vertical cross sectional view for explaining one phase of the manufacturing process flow of the NAND flash memory device of the second embodiment.

FIG. 12 is one example of a vertical cross sectional view for explaining one phase of the manufacturing process flow of the NAND flash memory device of the second embodiment.

FIG. 13 is one example of a vertical cross sectional view for explaining one phase of the manufacturing process flow of the NAND flash memory device of the second embodiment.

### DESCRIPTION

In one embodiment, a semiconductor device includes a semiconductor substrate; and a gate electrode disposed above the semiconductor substrate. The gate electrode includes a conductive film, a metal film, and a first insulating film. In a cross sectional view of the gate electrode, at least the metal film includes a receding portion receding in a lateral direction as compared to the first insulating film, and wherein a second insulating film is disposed in the receding portion and contacts sidewalls of the metal film.

A first embodiment of a semiconductor device is described hereinafter through a NAND flash memory device application with the accompanying drawings. The drawings are not drawn to scale and thus, do not reflect the actual measurements of the features such as the correlation of thickness to planar dimensions and the relative thickness of different layers. Further, directional terms such as up, down, lower, left, and right are used in a relative context with an assumption that the surface, on which circuitry is formed, of the later described semiconductor substrate faces up. Thus, the directional terms do not necessarily correspond to the directions based on gravitational acceleration. In the following description, XYZ orthogonal coordinate system is used for ease of explanation. In the coordinate system, the X direction and the Y direction indicate directions parallel to the surface of a semiconductor substrate and are orthogonal to one another.

### First Embodiment

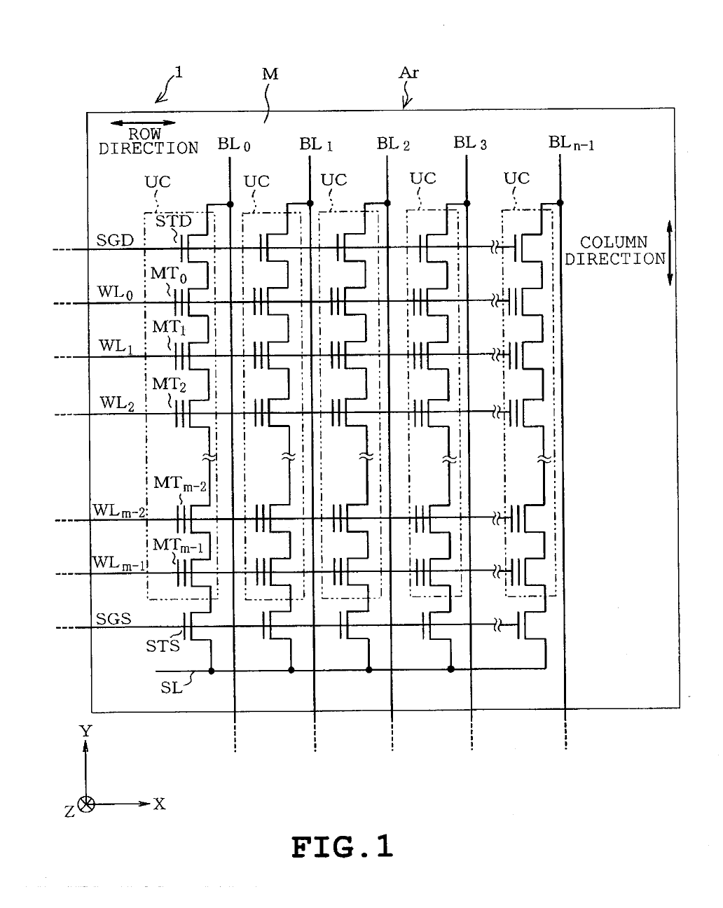

FIG. 1 is one example of a schematic diagram illustrating an electrical configuration of memory cell blocks of a NAND flash memory device. As shown in FIG. 1, NAND flash memory device 1 primarily comprises memory cell array Ar configured by multiplicity of memory cells arranged in a matrix.

Memory cell array Ar located in memory cell region M includes multiplicity of unit memory cells UC. Unit memory cells UC includes select transistors STD connected to bit lines BL₀ to Blₙ₋₁ and select transistors STS connected to source lines SL. Between select transistors STD and STS, m (m=2^{k}, for example m=32) number of series connected memory-cell transistors MT₀ to MTₘ₋₁, disposed between select transistors STD and STS.

Unit memory cells UC constitute a memory-cell block and a plurality of memory-cell blocks constitute memory cell array Ar. A single block comprises n number of unit memory cells UC, aligned along the row direction (X direction as viewed in FIG. 1). Memory cell array Ar constitutes a plurality of blocks aligned along the column direction (Y direction as viewed in FIG. 1). FIG. 1 only shows one block for simplicity.

The gates of select transistors STD are connected to control line SGD. The control gates of the m^{th} memory-cell transistors MTₘ₋₁ connected to bit lines BL₀ to Blₙ₋₁ are connected to word line WLₘ₋₁. The control gates of the third memory-cell transistors MT₂ connected to bit lines BL₀ to Blₙ₋₁ are connected to word line WL₂. The control gates of second memory-cell transistors MT₁ connected to bit lines BL₀ to Blₙ₋₁ are connected to word line WL₁. The control gates of first memory-cell transistors MT₀ connected to bit lines BL₀ to Blₙ₋₁ are connected to word line WL₀. The gates of select transistors STS connected to source lines SL are connected to control line SGS. Control lines SGD, word lines WL₀ to WLₘ₋₁, control lines SGS and source lines SL each intersect with bit lines BL₀ to Blₙ₋₁. Bit lines BL₀ to Blₙ₋₁ are connected to a sense amplifier not shown.

Gate electrodes of select transistors STD of the row-directionally aligned unit memory cells UC are electrically connected by common control line SGD. Similarly, gate electrodes of select transistors STS of the row directionally aligned unit memory cells UC are electrically connected by common control line SGS. The source of each select transistor STS is connected to common source line SL. Gate electrodes of memory-cell transistors MT₀ to MTₘ₋₁ of the row-directionally aligned unit memory cells UC are each electrically connected by word line WL₀ to WLₘ₋₁, respectively.

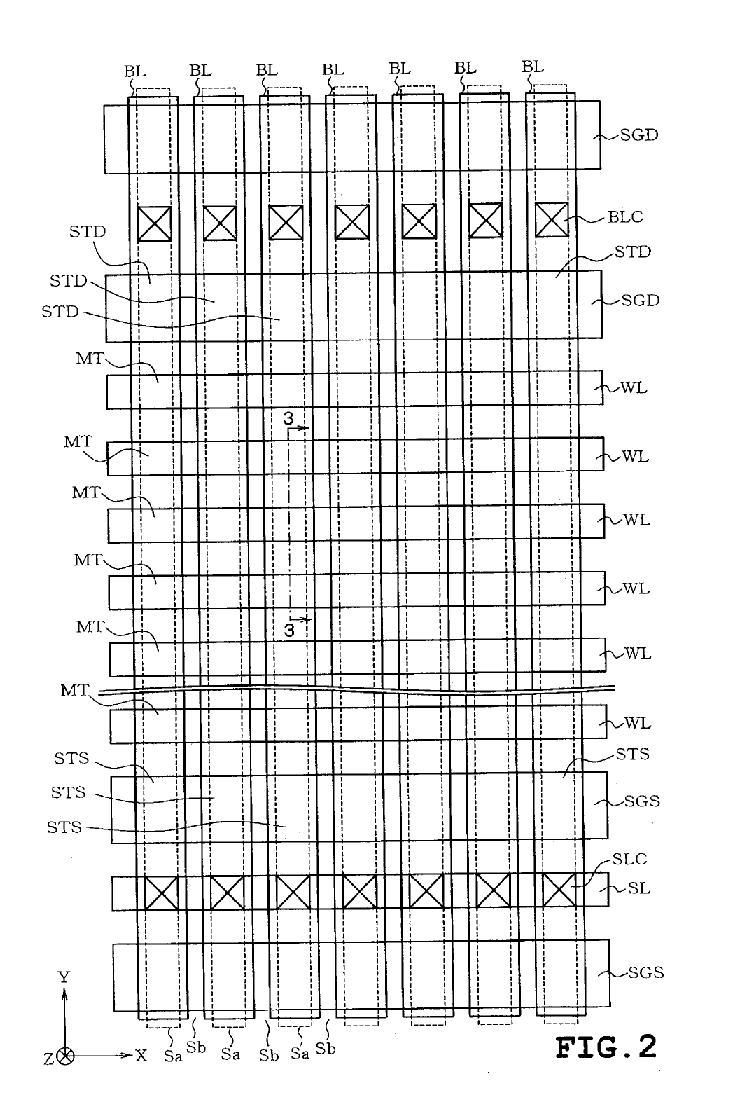

FIG. 2 is one schematic example of a planar layout of memory cell region M in part. Bit lines BL₀ to Blₙ₋₁ are also hereinafter referred to as bit line(s) BL. Word lines WL₀ to WLₘ₋₁ and memory-cell transistors MT₀ to MTₘ₋₁ are also hereinafter referred to as word line(s) WL, and memory-cell transistor(s) MT for simplicity.

As shown in FIG. 2, source lines SL, control lines SGS, word lines WL, and control lines SGD each run in the X direction (the Row Direction indicated in FIG. l) and are spaced from one another in the Y direction (the Column Direction indicated in FIG. 1). Bit lines BL are aligned along the Y direction and isolated from one another in the X direction by a predetermined distance.

Element isolation regions Sb run in the Y direction. The element isolation region Sb takes an STI (shallow trench isolation) structure in which the trench is filled with an insulating film. Element isolation regions Sb are spaced from one another in the X direction by a predetermined distance. Thus, element isolation regions Sb isolate element regions Sa, formed in a surface layer of semiconductor substrate 2 along the Y direction, in the X direction. In other words, element isolation region Sb is located between element isolation regions Sa, meaning that the semiconductor substrate, is delineated into element regions Sa by element isolation region Sb.

Word lines WL extend in a direction orthogonal to element regions Sa (the X direction as viewed in FIG. 2). Word lines WL are spaced from one another in the Y direction by a predetermined distance. Above element region Sa located at the intersection with word line WL, memory-cell transistor MT is disposed. The Y-directionally adjacent memory-cell transistors MT constitute a part of a NAND string also referred to as a memory-cell string.

Above element region Sa located at the intersection with control lines SGS and SGD, select transistors STS and STD are disposed. Select transistors STS and STD are disposed Y-directionally adjacent to the outer sides of memory cell transistors MT (memory cell MG1) located at both ends of the NAND string.

Select transistors STS connected to source line SL are aligned in the X direction and gate electrodes of select transistors STS are electrically interconnected by control line SGS. The gate electrode of select transistor STS is formed above element region Sa intersecting with control line SGS. Source contact SLC is provided at the intersection of source line SL and bit line BL.

Select transistors STD are aligned in the X direction and gate electrodes of select transistors STD are electrically interconnected by control line SGD. The gate electrode of select transistor STD is formed above element region Sa intersecting with control line SGD. Bit line contact BLC is provided in element region Sa located between the adjacent select transistors STD.

The foregoing description outlines the basic structures of NAND flash memory device of the first embodiment.

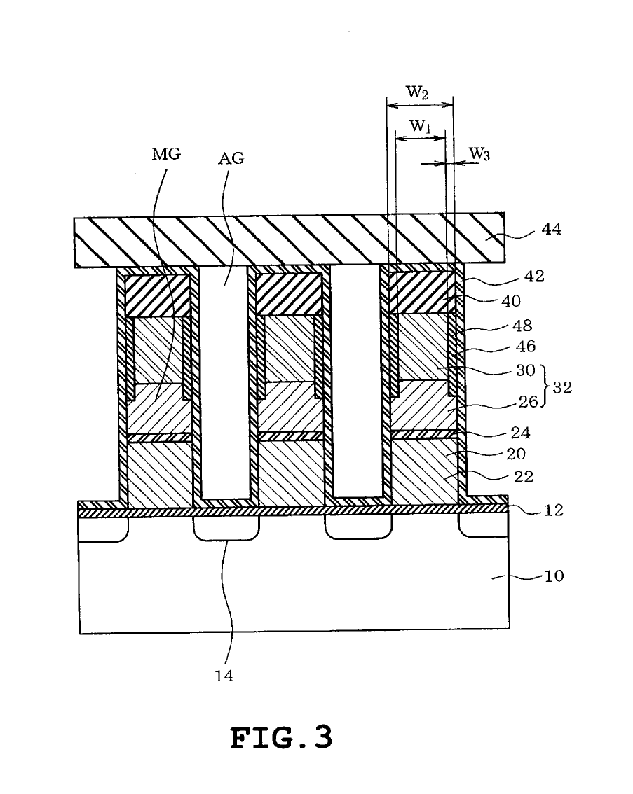

The structures of NAND flash memory device 1 of the first embodiment will be described in detail with reference to FIGS. 3 to 9.

FIG. 3 is one example of a view schematically illustrating the cross sectional structures of memory cell transistor MT taken along line 3-3 of FIG. 2.

As shown in FIG. 3, memory cell gate electrodes MG are disposed above semiconductor substrate 10. Semiconductor substrate 10 may comprise, for example, a p conductive-type silicon substrate. Semiconductor substrate 10 including a p-well may also be used. Gate insulating film 12 is formed above semiconductor substrate 10. Gate insulating film 12 may comprise, for example, a silicon oxide film formed by thermal oxidation. An oxynitride film may be used instead of a silicon oxide film.

Memory cell gate electrode MG is formed by stacking floating gate electrode 20, interelectrode insulating film 24, control gate electrode 32, and first insulating film 40 above gate insulating film 12. Floating gate electrode 20 may comprise, for example, a polysilicon film doped with impurities. The impurities may comprise, for example, boron (B). Interelectrode insulating film 24 may comprise, for example, an ONO (Oxide Nitride Oxide) film made of a stack of silicon oxide film/silicon nitride film/silicon oxide film. Control gate electrode 32 may comprise, for example, a stack of second polysilicon film 26 doped with impurities and metal film 30 stacked one over the other. Metal film 30 has width W₁. The upper portion of second polysilicon film 26 has width W₁ and the lower portion of second polysilicon film 26 has width W₂. Impurities introduced into second polysilicon film 26 may comprise, for example, boron. Metal film 30 may comprise, for example, tungsten (W). A barrier metal film may be provided between metal film 30 and second polysilicon film 26. The barrier metal film may comprise, for example, tungsten nitride (WN). In such case, metal film 30 comprises, for example, a stack of tungsten nitride/tungsten. The barrier metal film is used, for example, to prevent reaction between polysilicon constituting second polysilicon film 26 and metal film 30 comprising, for example, tungsten.

Interelectrode insulating film 24 is provided between floating gate electrode 20 and control gate electrode 32. Floating gate electrode 20 and control gate electrode 32 are insulated from one another by interelectrode insulating film 24. Above control gate electrode 32, first insulating film 40 is disposed. First insulating film 40 has width W₂. First insulating film 40 may comprise, for example, a silicon nitride film.

Receded portion (constriction) is formed continuously along the sidewalls of metal film 30 and the upper portions of the sidewalls of second polysilicon film 26 which have width W₁. Receding portion 48 is filled with sidewall protection film 46. Sidewall protection film 46 contacts the sidewalls of metal film 30. Sidewall protection film 46 contacts the sidewalls of the upper portions of second polysilicon film 26 having width W₁ (receding portion 48). Sidewall protection film 46 does not contact the sidewalls of interelectrode insulating film 24. Sidewall protection film 46 may comprise, for example, a silicon oxide film or a silicon nitride film. At least the sidewalls of metal film 30 are covered by protection film 46.

Metal film 30 is receded in the width direction (lateral direction) as compared to first insulating film 40. Width W₁ of metal film 30 is less than width W₂ of first insulating film 40 (W₁<W₂). When the width of the receding portion (the width of the constriction) is represented as W₃, the thickness of sidewall protection film 46 is approximately W₃ which may be represented as W₃=(W₂−W₁)/2. The sum of width W₁ of metal film 30 and width W₃ of sidewall protection film 46 is approximately W₂.

The upper surface of gate insulating film 12 and the surfaces of memory cell gate electrode MG and sidewall protection film 46 are covered with second insulating film 42. Second insulating film 42 may comprise, for example, a silicon oxide film. Second insulating film 42 is used as a liner film. The sidewalls of metal film 30 are covered by a stack of sidewall protection film 46 and second insulating film 42.

Gaps or unfilled gaps exist between memory cell gate electrodes MG. The upper portions of memory cell gate electrodes MG and the gaps are covered by third insulating film 44 acting like a lid. Third insulating film 44 may comprise, for example, a silicon oxide film formed by plasma CVD. Third insulating film 44 is formed under conditions providing poor step coverage and thus, does not completely fill air gap AG. Third insulating film 44 extends over and across memory cell gate electrodes MG and air gaps AG so as to cover them. Air gap AG reduces the parasitic capacitance between memory cell gate electrodes MG.

In the surface of semiconductor substrate 10 located on both sides of memory cell gate electrodes MG, source/drain region 14 is formed. Source/drain region 14 is an n-type impurity layer region doped with impurities such as phosphorous.

In the first embodiment described above, at least the sidewalls of metal film 30 are covered with sidewall protection film 46. Thus, it is possible to inhibit scattering of metal material, such as tungsten constituting metal film 30, during the manufacturing process flow. It is thus, possible to prevent metal contamination of gate insulating film 12, floating gate electrode 20, interelectrode insulating film 24, or the like. As a result, it is possible to inhibit degradation of memory properties and thereby provide a reliable semiconductor device.

### (Manufacturing Method)

Next, a description will be given on one example of a manufacturing process flow of the semiconductor device of the first embodiment. The following descriptions will focus on the features of the first embodiment and thus, known process steps may be added to the process flow as required. Further, the sequence of the process steps may be rearranged if practicable.

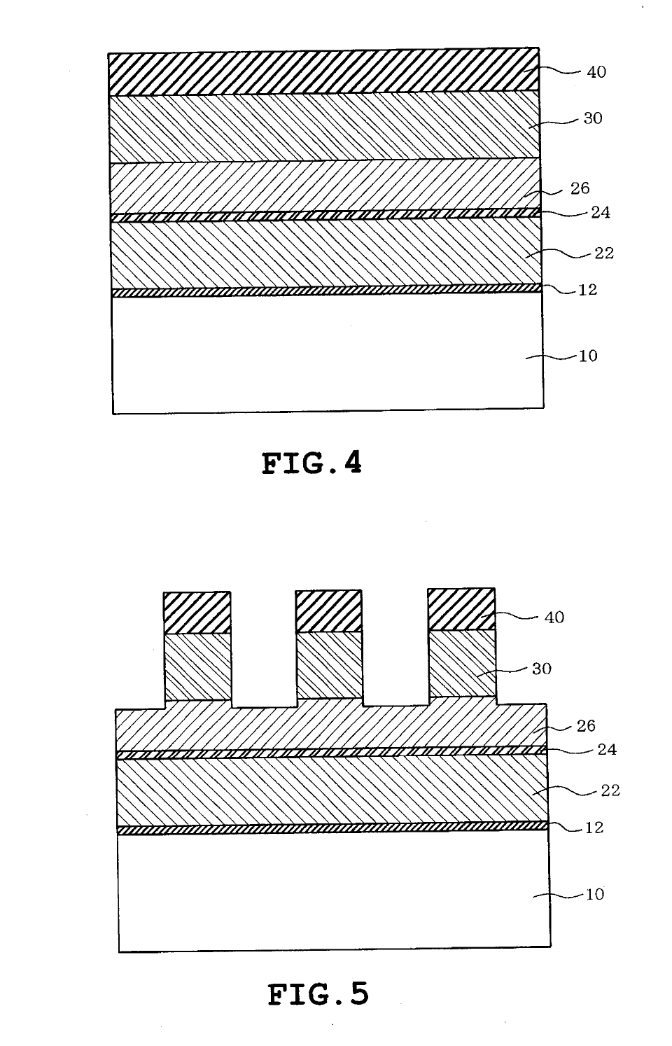

FIGS. 4 to 8 each exemplify one process step of the manufacturing process flow of a NAND flash memory device of the first embodiment and are referred to for describing the manufacturing process flow. FIGS. 4 to 8 are each an example of a cross sectional view taken along line 3-3 of FIG. 2 and indicate the cross section of memory cell transistor MT.

First a brief description will be given on the process steps carried out in obtaining the structure illustrated in FIG. 4. Gate insulating film 12, first polysilicon film 22 (floating gate electrode 20), and a mask nitride film are formed above semiconductor substrate 10 and are selectively etched by dry etching using lithography and RIE (Reactive Ion Etching). Silicon substrate 10 is also etched at this instance to form element isolation trenches. A silicon oxide film (element isolation insulating film) is formed throughout the entire surface so as to fill the element isolation trenches and the gaps between floating gate electrodes 20 and to cover their upper portions. Next, the silicon oxide film is polished by CMP (Chemical Mechanical Polishing) so as to be receded to the height of the upper surface of the mask nitride film. Then, the upper surface of the silicon oxide film is receded by dry etching to a predetermined height located approximately at mid height of floating gate electrode 20. Then, the mask nitride film is etched away, for example, by using phosphoric acid (hot phosphoric acid) which is heated to approximately 140 degrees Celsius. The element isolation insulating film is formed in the above described manner. The region where the element isolation insulating film is formed serves as element isolation region Sb. Element isolation region Sb divides the surface of semiconductor substrate 10 in the X direction and the region located between element isolation regions Sb serves as element region Sa. Gate insulating film 12 may be formed, for example, by thermally oxidizing the surface of semiconductor substrate 10 in a dry O₂ ambient and in the temperature of 950 degrees Celsius. First polysilicon film 22 may be formed, for example, by depositing polysilicon by CVD (Chemical Vapor Deposition) and introducing impurities such as boron into the polysilicon by ion implantation.

Still referring to FIG. 4, interelectrode insulating film 24, control gate electrode 32, and first insulating film 40 are formed. Interelectrode insulating film 24 may comprise an ONO film as discussed earlier. ONO film may be formed, for example, by stacking silicon oxide film, silicon nitride film, and silicon oxide film one over the other by CVD. Control gate electrode 32 is formed by stacking second polysilicon film 26 and metal film 30 as discussed earlier. Metal film 30 may comprise a stack of films in which a barrier metal film is disposed in the lower portion. Second polysilicon film 26 may be formed, for example, by depositing polysilicon by CVD and introducing impurities such as boron into the polysilicon by ion implantation. Metal film 30 may comprise, for example, tungsten which may be formed by sputtering. When metal film 30 is formed as a stack of a barrier metal film and a metal film, the barrier metal film comprising, for example, tungsten nitride and the metal film comprising, for example, tungsten maybe formed one after another by sputtering. First insulating film 40 may comprise a silicon nitride film formed, for example, by CVD. First insulating film 40 may comprise a silicon oxide film instead of a silicon nitride film.

Referring now to FIG. 5, first insulating film 40 and metal film 30 are etched one after another by lithography and RIE. At this instance, a portion of the upper portion of second polysilicon film 26 is over etched so that the upper portion of second polysilicon film 26 is slightly receded in the up and down direction (Y direction).

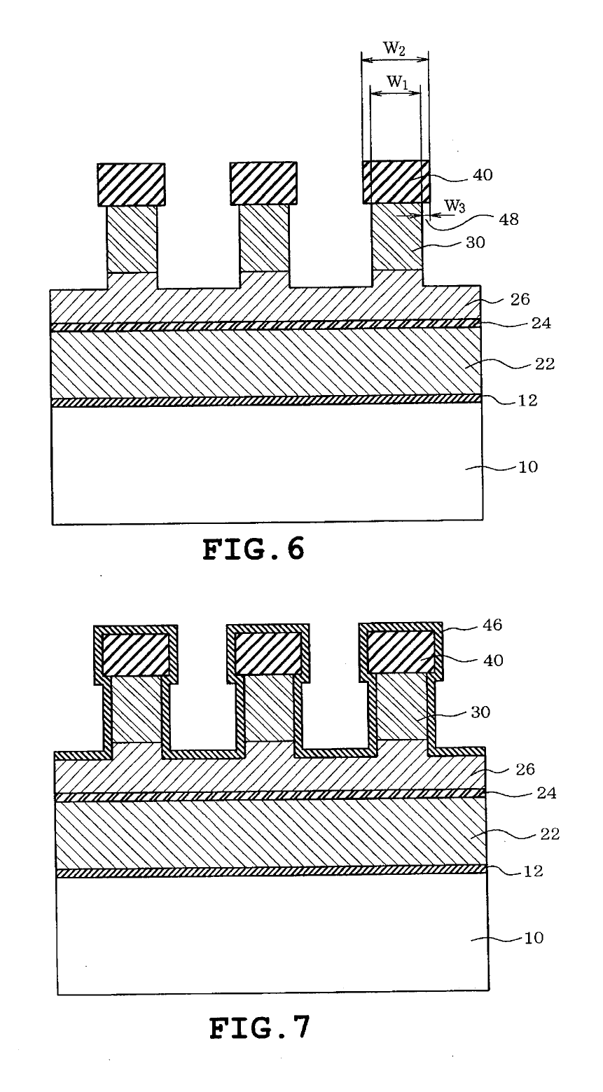

Referring now to FIG. 6, receding portion 48 (constriction) is formed by causing metal film 30 to recede by RIE. The etching uses an etch gas having a high CF₄ ratio or a high Cl₂ ratio. The etching progresses isotropically and under conditions that do not etch first insulating film 40. The etching etches second polysilicon film 26 as well to cause a portion of second polysilicon film 26 to recede like metal film 30 and thus, become a part of receding portion 48. First insulating film 40 has width W₂ and metal film 30 has width W₁. Metal film 30 is receded in the width direction (lateral direction) as compared to first insulating film 40. Width W₁ of metal film 30 is less than width W₂ of first insulating film 40 (W₁<W₂). The width of the receding portion (the width of the constriction) of metal film 30 measured from first insulating film 40 is W₃. Because the etching progresses isotropically, W₃ may be represented as W₃=(W₂−W₁)/2. Metal film 30 recedes so that first insulating film 40 hangs over receding portion 48 like a flange.

Referring now to FIG. 7, sidewall protection film 46 is formed throughout the entire surface. Sidewall protection film 46 may comprise, for example, a silicon nitride film. The silicon nitride film may be formed, for example, by CVD. The silicon nitride film is formed under conditions providing conformal coverage. Sidewall protection film 46 may be formed so as to be as thick as width W₃ of the receding portion. Sidewall protection film 46 is formed so as to precisely follow the surface profile formed by metal film 30, first insulating film 40, and second polysilicon film 26. Sidewall protection film 46 may be formed by ALD (Atomic Layer Deposition) instead of CVD. It is possible to form finer films by ALD as compared to CVD normally used. Further, sidewall protection film 46 may comprise a silicon oxide film instead of a silicon nitride film.

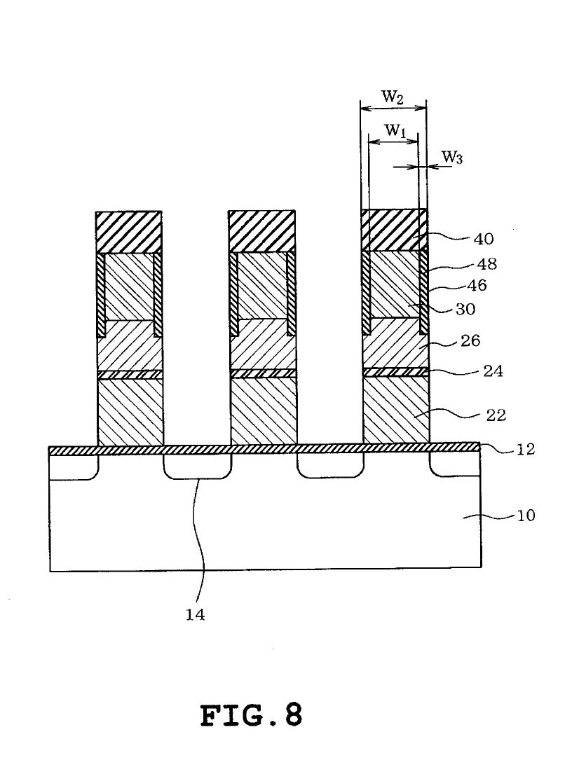

Referring now to FIG. 8, RIE is performed. The etching is carried out in the amount of thickness of sidewall protection film 46. Then, the etching progresses through second polysilicon film 26, interelectrode insulating film 24, and first polysilicon film 22 one after another and stops on gate insulating film 12. The etching is carried out using first insulating film 40 as a mask. Thus, first insulating film 40 needs to be sufficiently thick in anticipation of the amount lost by the etching.

The sidewall film 46 located along metal film 30 and second polysilicon film 26 is protected by the portion of first insulating film 40 shaped like a flange, and thus, is not removed or significantly reduced in amount by the etching. As a result, sidewall protection film 46 remains in sufficient thickness inside receding portions 48 located along the sidewalls of metal film 30 after the etching, and thus, provides sufficient protection of the sidewalls of metal film 30. Sidewall protection film 46 located along the sidewalls of first insulating film 40 may be almost completely removed or may remain in a small thickness.

The above described etching process step obtains memory cell gate electrode MG which is substantially vertically aligned with the sidewalls of first insulating film 40. Sidewall protection film 46 fills receding portions 48 along the sidewalls of metal film 30 and constitutes the substantially vertical sidewalls of memory cell gate electrode MG. Sidewall protection film 46 below the portion of first insulating film 40 shaped like a flange is protected by the flange-like portion and thus, is inhibited from receding laterally and being removed. Thus, it is possible for sidewall protection film 46 to remain in sufficient thickness and thereby provide sufficient protection for the sidewalls of metal film 30.

When metal film 30 comprises a stack of tungsten nitride and tungsten films, sidewall protection film 46 covers the sidewalls of metal film 30 including the tungsten nitride and tungsten. Sidewall protection film 46 further covers the upper portions of sidewalls of second polysilicon film 26 disposed below metal film 30. The sidewalls of metal film 30 are covered by sidewall protection film 46 and are not exposed during the etching. Thus, metal material such as tungsten constituting metal film 30 does not scatter by the sputtering effect caused by physical bombardment occurring in the etching atmosphere. Further, sidewall protection film 46 comprising a silicon nitride film formed by ALD is finer compared to a film formed by CVD, and thus, it is possible for sidewall protection film 46 to protect the sidewalls of metal film 30 more effectively.

Next, a cleaning step is carried out to remove the re-deposits, or the like resulting form the etching. The cleaning step includes, for example, treatments by diluted hydrofluoric acid solution and ammonia hydrogen peroxide solution carried out one after another which is followed by IPA (Isopropyl Alcohol) dry. The sidewalls of metal film 30 are covered by sidewall protection film 46 and thus, are not exposed to the ambient. Thus, metal film 30 does not contact the cleaning liquid during the cleaning step.

The cleaning liquid removes the re-deposits and further removes metal contaminants attached to the surface of the structure. The cleaning liquid is further effective in dissolving metal materials. Thus, when metal film 30 is exposed, the cleaning liquid comes in contact with metal film 30 and the metal constituent of metal film 30 dissolves into the cleaning liquid.

The metal material dissolved into the cleaning liquid may re-attach to floating gate electrode 20, interelectrode insulating film 24, or the surface of semiconductor substrate 10. Thus, when the cleaning is carried out with metal film 30 exposed, the amount of re-attachment of the dissolved metal material may surpass the amount of removal of metal material attached to the surface of semiconductor substrate 10, or the like.

Similar phenomenon may be encountered when a barrier metal film is provided to metal film 30 and the barrier metal contains metal material. For example, when the barrier metal film comprises tungsten nitride, tungsten may dissolve into the cleaning liquid and contaminate other portions of memory cell gate electrode MG, the surface of semiconductor substrate 10, or the like.

A NAND flash memory device carrying metal contaminants on the surfaces of floating gate electrodes 20, gate insulating film 12, interelectrode insulating film 24, or the like, may easily release electrons injected into floating gate electrodes 20. Such difficulty in retaining electrons in floating gate electrode 20 may degrade the data retention capabilities of NAND flash memory device.

In the above described first embodiment, because the sidewalls of metal film 30 are covered by sidewall protection film 46 and thus, are not exposed, the metal constituents of metal film 30 such as tungsten does not dissolve into the cleaning liquid. Since metal material does not dissolve into the cleaning liquid, floating gate electrode 20, interelectrode insulating film 24, gate insulating film 12, or the like, is free of re-attachment of metal material to thereby prevent metal contamination. Further, sidewall protection film 46 comprising a silicon nitride film formed by ALD is finer compared to a film formed by CVD, and thus, it is possible for sidewall protection film 46 to protect the sidewalls of metal film 30 more effectively.

Then, ion implantation is carried out to implant, for example, phosphorous into the surface of semiconductor substrate 10. The ion implantation of phosphorous may be carried out at the acceleration energy of 20 Kev, and in the dose of 5×10¹⁴ atms/cm². As a result, source/drain region 14 is formed in the surface of semiconductor substrate 10 located between memory cell gate electrodes MG.

Referring now to FIG. 3, second insulating film 42 and third insulating film 44 are formed one after another throughout the entire surface. Second insulating film 42 comprises, for example, a silicon oxide film formed by CVD under conditions providing good step coverage. Second insulating film 42 conformally covers the surface formed of memory cell gate electrode MG and sidewall protection film 46. Third insulating film 44 comprises, for example, a silicon oxide film formed by CVD under conditions providing poor step coverage. As a result, it is possible for third insulating film 44 to extend across the upper portions of memory cell gate electrodes MG like a lid so as to leave the gaps between memory cell gate electrodes MG unfilled. Third insulating film 44 does not fill the interior of the gaps between memory cell gate electrodes MG. Third insulating film 44 is formed so as to extend across the upper surfaces of memory cell gate electrodes MG and cover the entire upper surface.

The gaps between memory cell gate electrodes MG are enclosed by third insulating film 44 in the above described manner to form air gaps AG. The foregoing process steps forms NAND flash memory device 1 of the first embodiment.

In the first embodiment described above, the sidewalls of metal film 30 are covered by sidewall protection film 46. Further, metal film 30 is formed so as to be receded relative to first insulating film 40. Because sidewall protection film 46 is formed in the receded portion, it is possible for sidewall protection film 46 to remain unremoved by the protection provided by first insulating film 40 during the etching. As a result, sufficient amount of sidewall protection film 46 remains along the sidewalls of metal film 30. Because the sidewalls of metal film 30 are covered by sidewall protection film 46 and not exposed, metal constituent of metal film 30 does not scatter during the etching. Further, metal material does not dissolve into the cleaning liquid during the cleaning. Thus, metal contamination is inhibited. As a result, it is possible to provide a semiconductor device possessing good properties and a manufacturing method for the same. By applying the first embodiment to a nonvolatile semiconductor storage device, it is possible to provide a nonvolatile semiconductor storage device possessing good memory properties and a manufacturing method for the same.

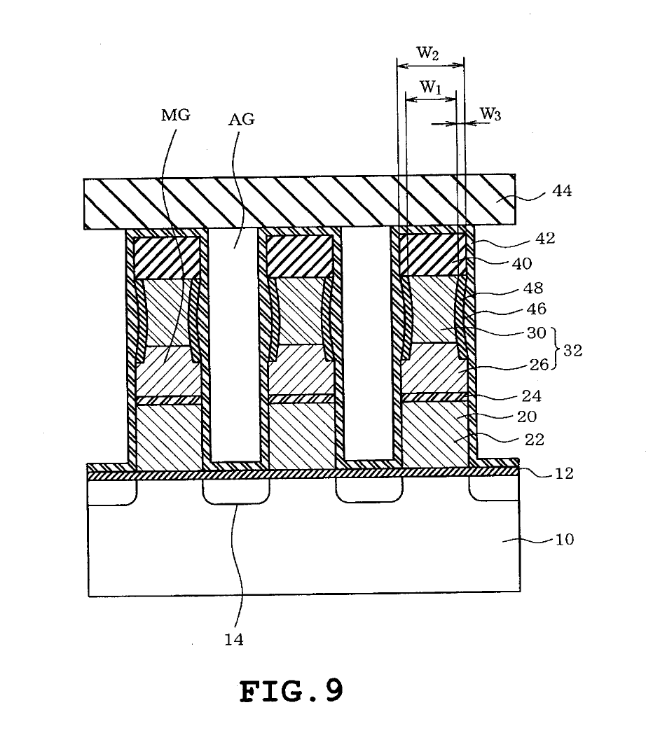

FIG. 9 is a figure for describing the sidewalls of metal film 30 assuming a bowing shape and illustrates one example of a cross sectional structure of a semiconductor device being subjected to the process flow earlier described with reference to FIG. 3. The lower portion of metal film 30 contacts second polysilicon film 26, whereas the upper portion of metal film 30 contacts first insulating film 40. A thermal treatment carried out during the manufacturing process flow may produce a gradient composition by the reaction of metal film 30 (e.g. tungsten) and second polysilicon film 26 (e.g. silicon) and metal film 30 and first insulating film 40 (e.g. silicon nitride film). In such case, the etch rate of the etching described with reference to FIG. 6 varies depending upon compositional ratio and thus, the shape of the receded metal film 30 may assume a bowing shape as shown in FIG. 9. It is possible to achieve the aforementioned effects in the above described structure as well since the sidewalls of metal film 30 are sufficiently covered by sidewall protection film 46 filled into receding portion 48.

### Second Embodiment

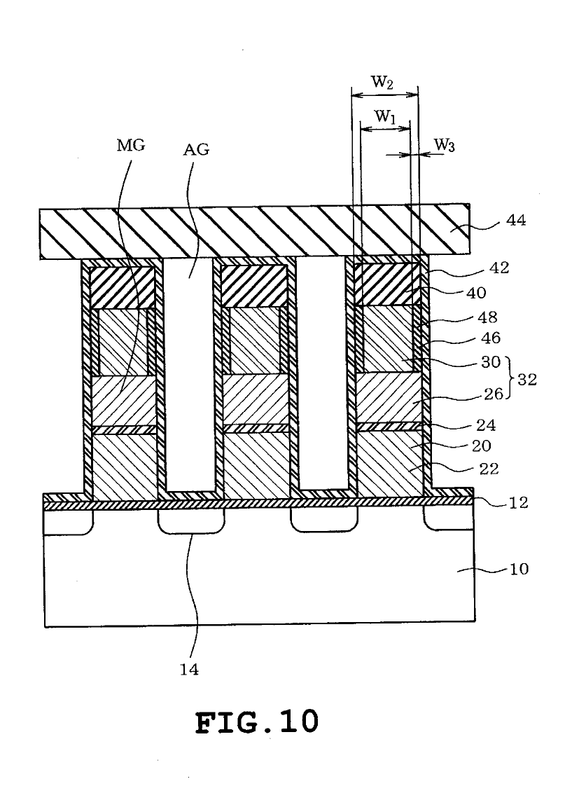

A description will be given on a second embodiment of a semiconductor device and its manufacturing method with reference to FIGS. 10 and 13. The basic structures of NAND flash memory device 1 described as the second embodiment of the semiconductor device is substantially identical to those of the first embodiment described through FIGS. 1 and 2. The elements identical to those of the first embodiment are represented by identical reference symbols and are not re-described.

FIG. 10 is one example of a view schematically illustrating the cross sectional structures of memory cell transistor MT taken along line 3-3 of FIG. 2. The cross sectional structure of memory cell transistor MT of the second embodiment differs from the first embodiment in that though metal film 30 is receded, second polysilicon film 26 is not receded. Thus, sidewall protection film 46 resides along the sidewalls of metal film 30. Sidewall protection film 46 and second polysilicon film 26 contact one another at the lower surface of sidewall protection film 46 and the upper surface of second polysilicon film 26.

The second embodiment provides effects similar to those of the first embodiment since the sidewalls of metal film 30 are covered by sidewall protection film 46 as was the case in the first embodiment.

Metal film 30 may assume a bowing shape in the second embodiment as well as shown in FIG. 9 of the first embodiment.

### (Manufacturing Method)

Next, a description will be given on one example of a manufacturing process flow of the semiconductor device of the second embodiment. The following descriptions will refer to the figures referred to in the first embodiment for explaining process steps that substantially identical to those of the first embodiment and will focus on the features of the second embodiment. As was the case in the first embodiment, known process steps may be added to the process flow as required. Further, the sequence of the process steps may be rearranged if practicable.

FIGS. 10 to 13 each exemplify one process step of the manufacturing process flow of a NAND flash memory device of the second embodiment and are referred to for describing the manufacturing process flow. FIGS. 10 to 13 are each an example of a cross sectional view taken along line 3-3 of FIG. 2 and indicate the cross section of memory cell transistor MT.

First, process steps described with reference to FIGS. 4 and 5 of the first embodiment are performed.

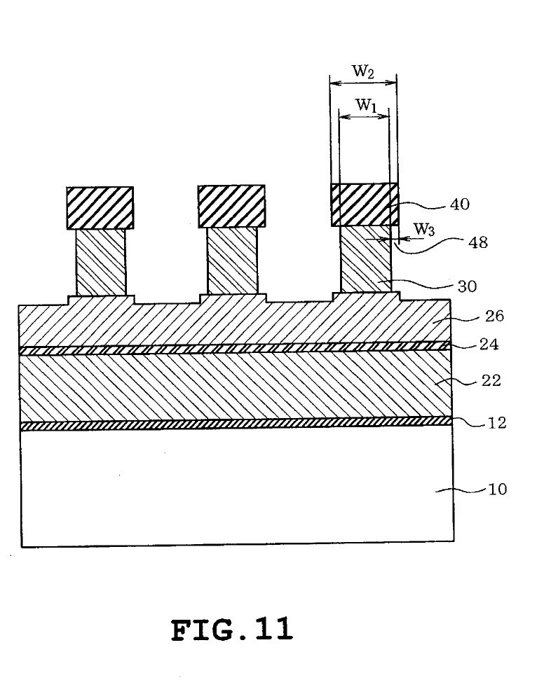

First a brief description will be given on the process steps carried out in obtaining the structure illustrated in FIG. 4. Then, as shown in FIG. 11, metal film 30 is receded to form receding portion 48 (constriction) by wet etching. The wet etching includes, for example, the following treatments. First, the surface of metal film 30 is oxidized by a chemical liquid including ammonia-hydrogen peroxide mixture. Then, the oxidized portion of metal is etched away by a wet etchant including diluted hydrofluoric acid solution. Thus, metal film 30 is receded to form receding portion 48. The wet etching selectively etches metal film 30 because of its high selectivity, whereas first insulating film 40 (silicon nitride film) and second polysilicon film 26 (polysilicon) are hardly etched. As a result, second polysilicon film 26 hardly recedes. First insulating film 40 has width W₂ and metal film 30 has width W₁. The width of the receding portion (the width of the constriction) of metal film 30 measured from first insulating film 40 is W₃. Width W₃ may be represented as W₃=(W₂−W₁)/2. Metal film 30 recedes so that first insulating film 40 hangs over receding portion 48 like a flange.

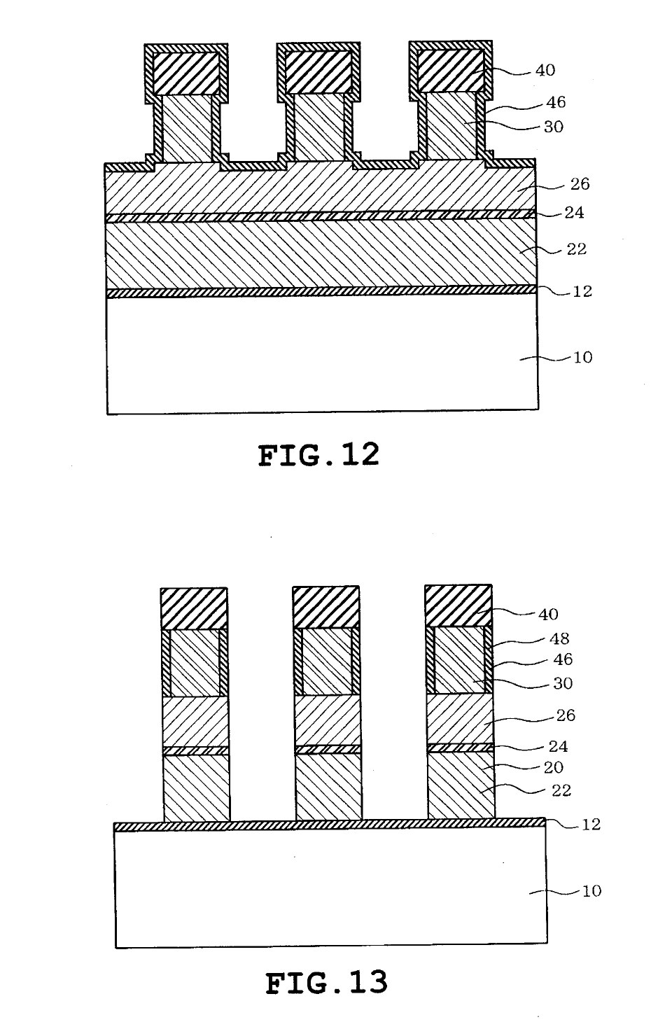

Referring now to FIG. 12, sidewall protection film 46 is formed throughout the entire surface. Sidewall protection film 46 may comprise, for example, a silicon nitride film. The silicon nitride may be formed, for example, by CVD. The silicon nitride film is formed under conditions providing conformal coverage.

Sidewall protection film 46 may be formed so as to be as thick as width W₃ of the receding portion. Sidewall protection film 46 is formed so as to precisely follow the surface profile formed by metal film 30, first insulating film 40, and second polysilicon film 26. Sidewall protection film 46 may be formed by ALD (Atomic Layer Deposition) instead of CVD.

Referring now to FIG. 13, RIE is performed. The etching is carried out in the amount of thickness of sidewall protection film 46. Then, the etching progresses through second polysilicon film 26, interelectrode insulating film 24, and first polysilicon film 22 one after another and stops on gate insulating film 12. The etching is carried out using first insulating film 40 as a mask. The above described etching process step obtains memory cell gate electrode MG which is vertically aligned with the sidewalls of first insulating film 40. Sidewall protection film 46 fills receding portions 48 along the sidewalls of metal film 30 and constitutes the substantially vertical sidewalls of memory cell gate electrode MG. Thus, it is possible for sidewall protection film 46 to remain in sufficient thickness along the sidewalls of metal film 30 and thereby provide sufficient protection for the sidewalls of metal film 30.

A cleaning step is carried out to remove the re-deposits, or the like, resulting form the etching. The cleaning step includes, for example, treatments by diluted hydrofluoric acid solution and ammonia hydrogen peroxide solution carried out one after another which is followed by IPA (Isopropyl Alcohol) dry. The sidewalls of metal film 30 are covered by sidewall protection film 46 and thus, do not contact the cleaning liquid. Because the sidewalls of metal film 30 are covered by sidewall protection film 46 and thus, are not exposed, the metal constituents of metal film 30 such as tungsten does not dissolve into the cleaning liquid. Since metal material does not dissolve into the cleaning liquid, floating gate electrode 20, interelectrode insulating film 24, gate insulating film 12, or the like, is free of re-attachment of metal material to thereby prevent metal contamination.

Ion implantation is carried out to implant, for example, phosphorous into the surface of semiconductor substrate 10 and thereby form source/drain region 14 in the surface of semiconductor substrate 10 located between memory cell gate electrodes MG.

Then, the process steps described with reference to FIG. 3 in the first embodiment are carried out to obtain NAND flash memory device 1 of the second embodiment as shown in FIG. 10.

As described above, sidewall protection film 46 fills receding portion 48 located in the sidewalls of metal film 30 in the second embodiment. Thus, it is possible to obtain effects similar to those of the first embodiment.

### Other Embodiments

The foregoing embodiments may be modified as follows.

ONO film was given as one example of interelectrode insulating film 24, however, other films such as a NONON (nitride-oxide-nitride-oxide-nitride) film or an insulating film having high dielectric constant may be used instead.

The above described embodiments were directed to NAND flash memory device, however, other embodiments may be directed to other nonvolatile semiconductor storage devices such as NOR flash memory and EERROM.

Semiconductor substrate 10 may comprise a p-type silicon substrate, a silicon substrate having a p well formed therein, or an SOI (Silicon On Insulator) including a p-type silicon region.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor storage device comprising:
a semiconductor substrate; and
a gate electrode disposed above the semiconductor substrate;
wherein the gate electrode includes a conductive film, a metal film, and a first insulating film and
wherein, in a cross sectional view of the gate electrode, at least the metal film includes a receding portion receding in a lateral direction as compared to the first insulating film, and
wherein a second insulating film is disposed in the receding portion and contacts sidewalls of the metal film.

2. The device according to claim 1, wherein the first insulating film is disposed above the receding portion and is shaped like a flange.

3. The device according to claim 1, wherein the metal film includes at least one of tungsten and tungsten nitride.

4. The device according to claim 1, wherein the second insulating film includes at least one of a silicon nitride film and a silicon oxide film.

5. The device according to claim 1, wherein the sidewalls of the metal film located in the receding portion assumes a bowing shape.

6. The device according to claim 1, further comprising a third insulating film covering a surface of the gate electrode and a surface of the second insulating film disposed in the receding portion.

7. The device according to claim 6, wherein the third insulating film includes at least one of a silicon nitride film and a silicon oxide film.

8. A semiconductor device, comprising:
a semiconductor substrate; and
a gate electrode disposed above the semiconductor substrate;
wherein the gate electrode includes a floating gate electrode, a control gate electrode, a first insulating film and a second insulating film stacked one over the other, and
wherein the second insulating film is disposed between the floating gate electrode and the control gate electrode, and
wherein the control gate electrode includes at least a conductive film and a metal film stacked one over the other, and
wherein, in a cross sectional view of the gate electrode, at least the metal film includes a receding portion receding in a lateral direction as compared to the first insulating film, and
wherein a third insulating film is disposed in the receding portion and contacts sidewalls of the metal film.

9. The device according to claim 8, wherein the third insulating film contacts sidewalls of the conductive film and the metal film and is spaced apart from the sidewalls of the second insulating film.

10. The device according to claim 8, wherein the first insulating film is disposed above the receding portion and is shaped like a flange.

11. The device according to claim 8, wherein the metal film includes at least one of tungsten and tungsten nitride.

12. The device according to claim 8, wherein the first insulating film includes at least one of a silicon nitride film and a silicon oxide film.

13. The device according to claim 8, wherein the third insulating film includes at least one of a silicon nitride film and a silicon oxide film.

14. The device according to claim 8, further comprising a fourth insulating film covering a surface of the gate electrode and a surface of the third insulating film disposed in the receding portion.

15. The device according to claim 14, wherein the fourth insulating film includes at least one of a silicon nitride film and a silicon oxide film.

16. A method of manufacturing a semiconductor device, comprising:
forming a conductive film, a metal film, and a first insulating film on a semiconductor substrate;
selectively etching the first insulating film, the metal film, and a portion of an upper portion of the conductive film;
etching at least the metal film with selectivity to the first insulating film to cause the metal film to recede in a lateral direction and form a receding portion;
forming a second insulating film throughout the underlying surface;
etching the conductive filmusing the first insulating film as a mask so that the second insulating film remains in the receding portion.

17. The method according to claim 16, further comprising forming a third insulating film covering surfaces of the conductive film, the metal film, and the first insulating film and a surface of the second insulating film disposed in the receding portion.

18. The method according to claim 16, wherein etching to form the receding portion is carried out under an isotropic condition.

19. The method according to claim 16, wherein the second insulating film is formed by atomic layer deposition.

20. The method according to claim 16, wherein the second insulating film and the third insulating film each include at least one of a silicon nitride film and a silicon oxide film.
